(19) United States
(12) Patent Application Publication
(10) Pub. No.: US 2026/0043763 A1
(43) Pub. Date: Feb. 12, 2026

(54) METHOD FOR DETECTING AGING OF BATTERY CELL, AND COMPUTER DEVICE

(71) Applicant: EVE ENERGY STORAGE CO., LTD., Wuhan (CN)

(72) Inventors: Qihua LI, Wuhan (CN); Haohao YI, Wuhan (CN); Zhenxing PAN, Wuhan (CN); Weijian YANG, Wuhan (CN); Xiang CHEN, Wuhan (CN)

(73) Assignee: EVE ENERGY STORAGE CO., LTD., Wuhan (CN)

(21) Appl. No.: 19/363,598

(22) Filed: Oct. 20, 2025

Related U.S. Application Data
(63) Continuation of application No. PCT/CN2023/137199, filed on Dec. 7, 2023.

(30) Foreign Application Priority Data
May 16, 2023 (CN) 202310551695.1

(51) Int. Cl. G01N 25/20; G01R 31/367; G01R 31/392; G01R 31/396

(52) U.S. Cl. CPC G01N 25/20; G01R 31/367; G01R 31/392; G01R 31/396

(57) ABSTRACT

A method includes: determining multiple charging phases and multiple discharging phases of a battery cell to be detected; calculating a first heat value and a second heat value of the battery cell to be detected based on a mass, a composite specific heat capacity, and a temperature of the battery cell to be detected; calculating a reversible heat ratio of the battery cell to be detected based on the first heat value and the second heat value; and determining whether the battery cell to be detected has an aging issue based on the reversible heat ratio.

This is a continuation application of International Patent Application PCT/CN2023/137199, filed on Dec. 7, 2023, which claims priority to Chinese Patent Application No. 202310551695.1, filed on May 16, 2023 with the China National Intellectual Property Administration. The contents of the above applications are incorporated by reference herein.

### TECHNICAL FIELD

The present disclosure relates to the field of battery detecting technology, and specifically relates to a method for detecting aging of a battery cell, and a computer device.

### BACKGROUND

In applications related to battery degradation and safety, the temperature characteristics of battery cells are primarily utilized in thermal runaway scenarios.

### SUMMARY

In a first aspect, embodiments of the present disclosure provide a method for detecting aging of a battery cell. The method including the following.

Multiple charging phases and multiple discharging phases of the battery cell to be detected are determined.

A first heat value and a second heat value of the battery cell to be detected are calculated based on the mass, the composite specific heat capacity, and the temperature of the battery cell to be detected, where the first heat value is the sum of the heat generated in the multiple charging phases of the battery cell to be detected, and the second heat value is the sum of the heat generated in the multiple discharging phases of the battery cell to be detected.

A reversible heat ratio of the battery cell to be detected is calculated based on the first heat value and the second heat value.

It is determined whether the battery cell to be detected has an aging issue based on the reversible heat ratio.

In a second aspect, embodiments of the present disclosure provide a computer device. The computer device includes one or more processors, a memory, and one or more applications, where the one or more applications are stored in the memory and configured to cause, when executed by the one or more processors, the one or more processors to perform the method for detecting aging of a battery cell according to the first aspect.

### BRIEF DESCRIPTION OF THE DRAWINGS

FIG. 1 is a flowchart of a method for detecting aging of a battery cell, according to some embodiments of the present disclosure.

FIG. 2 is a schematic diagram illustrating the division of charging and discharging phases of a battery cell to be detected, according to some embodiments of the present disclosure.

FIG. 3 is a schematic diagram illustrating the division of charging and discharging energy proportions of a battery cell to be detected, according to some embodiments of the present disclosure.

FIG. 4 is a flowchart of another method for detecting aging of a battery cell, according to some embodiments of the present disclosure.

FIG. 5 is a structural diagram of a device for detecting aging of a battery cell, according to some embodiments of the present disclosure.

### DETAILED DESCRIPTION

It should be noted that the terms “first”, “second” and the like in the specification, claims and accompanying drawings of the present disclosure are configured to distinguish between different objects, and are not configured to limit a particular order. The following embodiments of the present disclosure may be performed individually, and the embodiments may also be performed in combination with each other. The embodiments of the present disclosure are not specifically limited in this regard.

In applications related to battery degradation and safety, the temperature characteristics of battery cells are primarily utilized in thermal runaway scenarios. However, from the perspective of electrochemical energy conversion and fundamental principles, the temperature characteristics of a battery are an important indicator of its service life.

Real-time operational temperature data of batteries can be collected and stored using mature sensor technologies, and thermal variation states of batteries can be calculated and monitored in bulk at high speed in real time through computing systems. Nevertheless, there are fewer methods that utilize thermal characteristics for battery capacity or lifespan degradation analysis, resulting in a gap in applying temperature variation characteristics to the detection of battery operating states.

Considering the above-described situation, embodiments of the present disclosure provide a method and device for detecting aging of a battery cell, and a computer device, and aim to address the technical problem in the related art where temperature variation characteristics are not utilized to detect battery aging, which can monitor the aging of the battery cell by utilizing the temperature variation characteristics of the battery cell in real time.

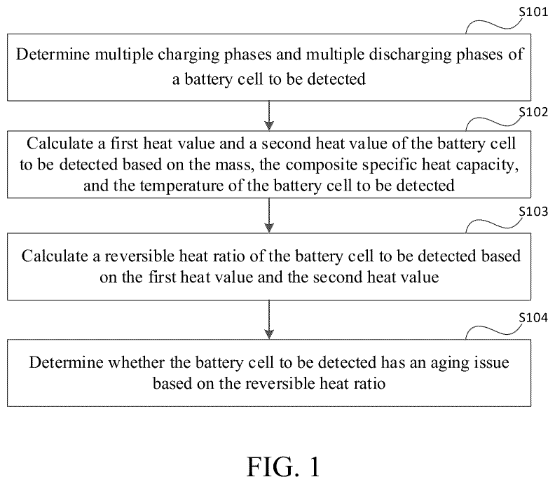

FIG. 1 is a flowchart of a method for detecting aging of a battery cell, according to some embodiments of the present disclosure.

As shown in FIG. 1, the method of detecting aging of a battery cell includes steps S101, S102, S103, and S104.

In S101, multiple charging phases and multiple discharging phases of the battery cell to be detected are determined.

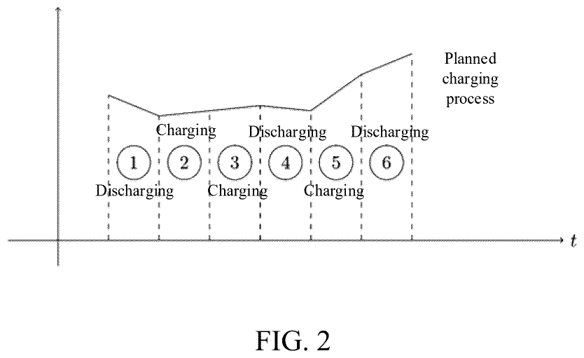

For example, the battery cell to be detected during use may have multiple charging or discharging phases over a period of time. FIG. 2 is a schematic diagram illustrating the division of the charging and discharging phases of the battery cell to be detected according to some embodiments of the present disclosure, assuming that there are multiple charging and discharging phases of the battery cell to be detected over a period of time, which are divided into six phases as shown in FIG. 2, with phase \textcircled{1} being a discharging phase, phase \textcircled{2} being a charging phase, phase \textcircled{3} being a charging phase, phase \textcircled{4} being a discharging phase, phase \textcircled{5} being a charging phase, and phase \textcircled{6} being a discharging phase.

Optionally, step S101, for example, includes: detecting a current direction of the battery cell to be detected within a preset time period, and determining a corresponding charging or discharging phase of the battery cell to be detected within the preset time period based on the detected current direction.

For example, the current direction in the battery cell to be detected may be used to indicate whether the battery cell to be detected is charging or discharging at the current time. To improve detection efficiency and reduce detection-related computational load, the charging and discharging process of the battery cell to be detected within a certain period of time may be divided, i.e., the current direction of the battery cell to be detected within the preset time period is detected, thereby dividing the charging and discharging process of the battery cell to be detected within the preset time period.

In S102, a first heat value and a second heat value of the battery cell to be detected are calculated based on the mass, the composite specific heat capacity, and the temperature of the battery cell to be detected, where the first heat value is the sum of heat generated in the multiple charging phases of the battery cell to be detected, and the second heat value is the sum of heat generated in the multiple discharging phases of the battery cell to be detected.

For example, after dividing the charging and discharging process of the battery cell to be detected within the preset time period, the sum (i.e., the above-described first heat value) of the heat generated in the multiple charging phases is calculated, and the sum (i.e., the above-described second heat value) of the heat generated in the multiple discharging phases is calculated. As shown in FIG. 2, taking the charging and discharging process of the battery cell to be detected in FIG. 2 as an example, the first heat value is the sum of the heat values of \textcircled{2}, \textcircled{3}, and \textcircled{5} phases, and the second heat value is the sum of the heat values of \textcircled{1}, \textcircled{4}, and \textcircled{6} phases.

In S103, a reversible heat ratio of the battery cell to be detected is calculated based on the first heat value and the second heat value.

Optionally, step S103, for example, includes the following.

The reversible heat ratio of the battery cell to be detected is calculated using the fifth formula:

$${η}_{rev} ( t ) = \frac{\vert {Q}_{Char} - {Q}_{Dis} \vert / 2}{{Q}_{Char} + {Q}_{Dis}} ,$$

where Q_{Char} represents the first heat value, Q_{Dis} represents the second heat value, and ηᵣₑᵥ(t) represents the reversible heat ratio of the battery cell to be detected.

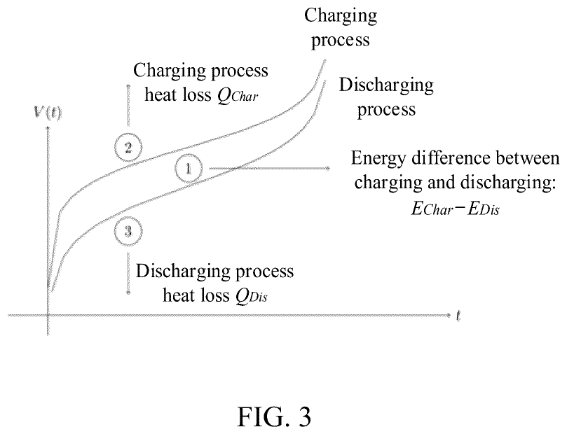

For example, the reversible heat ratio refers to the ratio of half of the absolute value of the difference between the heat generated in the charging and discharging phases of the battery cell to be detected to the total sum of heat generated. FIG. 3 is a schematic diagram illustrating the division of charging and discharging energy proportions of the battery cell to be detected, according to some embodiments of the present disclosure. As shown in FIG. 3, the second region above the charging process curve represents a charging process heat loss Q_{Char}, i.e., the first heat value, and the third region below the discharging process curve represents a discharging process heat loss Q_{Dis}, i.e., the second heat value. The reversible heat ratio ηᵣₑᵥ(t) is

$$\frac{\vert {Q}_{Char} - {Q}_{Dis} \vert / 2}{{Q}_{Char} + {Q}_{Dis}} .$$

In S104, it is determined whether the battery cell to be detected has an aging issue based on the reversible heat ratio.

Optionally, step S104, for example, includes: comparing the reversible heat ratio with a preset heat threshold; and when the reversible heat ratio is less than the preset heat threshold, determining that the battery cell to be detected has an aging issue.

For example, after calculating the reversible heat ratio of ηᵣₑᵥ(t), the reversible heat ratio of ηᵣₑᵥ(t) may be compared with the preset heat threshold of ηᵣₑᵥ(t)₀. Since reversible heat requires the existence of a certain reasonable ratio, when ηᵣₑᵥ(t)<ηᵣₑᵥ(t)₀, it indicates that the reversible heat ratio of the battery cell to be detected does not reach the demand value, and that there is an aging issue of the battery cell to be detected; and when ηᵣₑᵥ(t) ηᵣₑᵥ(t)₀, it indicates that the reversible heat ratio exceeds the preset heat threshold, and that the battery cell to be detected is in a normal working state without aging issue.

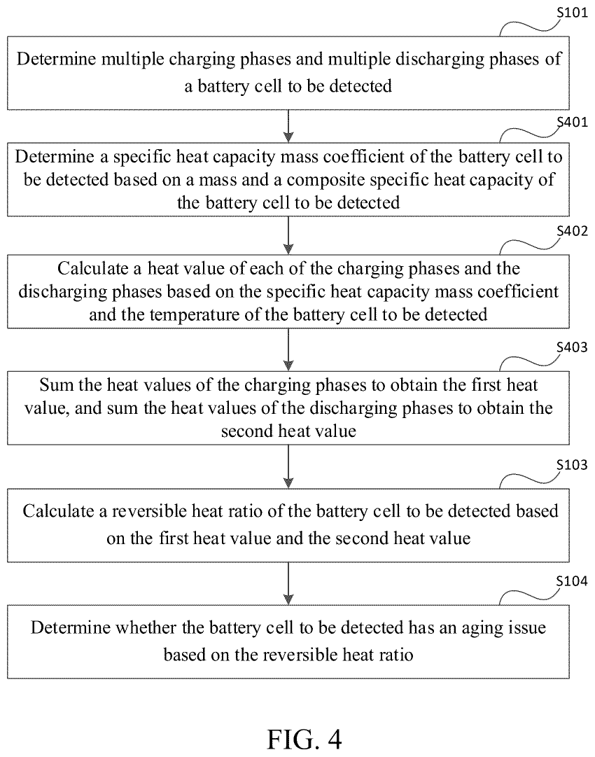

On the basis of the above technical solutions, FIG. 4 is a flowchart of another method for detecting aging of a battery cell, according to some embodiments of the present disclosure. As shown in FIG. 4, step S102 includes steps S401, S402, and S403.

In S401, a specific heat capacity mass coefficient of the battery cell to be detected is determined based on a mass and a composite specific heat capacity of the battery cell to be detected.

For example, since the battery cell to be detected is made of a variety of materials, each of which has a different specific heat capacity, and each of which has a different mass used, the specific heat capacity mass coefficient of the battery cell to be detected may be calculated based on the masses and specific heat capacities of the respective materials used in the battery cell to be detected.

Optionally, step S401 includes: determining the specific heat capacity mass coefficient of the battery cell to be detected, based on the mass and the composite specific heat capacity of the battery cell to be detected, using the first formula:

$${CM}_{Cell} ( t ) = ( {\sum }_{j} {C}_{j} ( t ) {M}_{j} ( t ) )$$

where CM_{Cell}(t) represents the specific heat capacity mass coefficient at moment t, Cⱼ(t) represents the composite specific heat capacity at moment t, Mⱼ(t) represents the mass of each material in the battery cell to be detected at moment t, and j represents an index reflecting the number of material types in the battery cell to be detected.

Exemplarily, assuming that a battery cell to be detected is made of three materials, the battery cell to be detected has the specific heat capacity mass coefficient of CM_{Cell}(t)=C₁(t)M₁(t)+C₂(t)M₂(t)+C₃(t)M₃(t). With the use of the battery cell to be detected, different degrees of loss will be generated. To calculate more accurately, the mass and the composite specific heat capacity of the battery cell to be detected may be acquired at the same moment, so that the mass of each of the materials of the battery cell to be detected and the specific heat capacity of the material are acquired at moment t.

In S402, a heat value of each of the charging phases and the discharging phases is calculated based on the specific heat capacity mass coefficient and the temperature of the battery cell to be detected.

For example, to make the calculations more accurate, the heat values of the multiple charging and discharging phases are calculated separately using the calculated specific heat capacity mass coefficient.

Optionally, step S402 includes: calculating the heat value of each charging or discharging phase, based on the specific heat capacity mass coefficient and the temperature of the battery cell to be detected, using the second formula:

$$Δ Q ( {t}_{n} ) = {\sum }_{n} {CM}_{Cell} ( {t}_{n} ) * Δ T ( {t}_{n} ) * Δ {t}_{n}$$

where ΔQ(tₙ) represents the heat value of each charging or discharging phase, CM_{Cell}(t) represents the specific heat capacity mass coefficient at moment t, ΔT(tₙ) represents the temperature of the battery cell to be detected at moment t, Δtₙ represents the duration of each charging or discharging phase, and n represents an index reflecting the number of time periods subdivided in each charging or discharging phase.

For example, one charging phase or one discharging phase may be subdivided into n time periods. The duration of each time period is Δtₙ, and the temperature change within the time period is ΔT(tₙ). Then the heat generated during the n time periods in the one charging phase or one discharging phase may be calculated using the specific heat capacity mass coefficient CM_{Cell}(tₙ), which is summed up to be the heat generated during each charging or discharging phase, i.e., ΔQ(tₙ).

In S403, the heat values of the charging phases are summed to obtain the first heat value, and the heat values of the discharging phases are summed to obtain the second heat value.

Optionally, step S403 includes: calculating the first heat value using the third formula:

$${Q}_{Char} = {\sum }_{Char - i} Δ Q ( {t}_{Char - i} )$$

where Q_{Char} represents the first heat value, ΔQ(t_{Char-i}) represents the heat value of the battery cell to be detected at each charging phase calculated according to the second formula, and Char-i represents an index reflecting the number of time periods marked in the charging phases of the battery cell to be detected; and
calculating the second heat value using the fourth formula:

$${Q}_{Dis} = {\sum }_{Dis - i} Δ Q ( {t}_{Dis - i} )$$

where Q_{Dis} represents the second heat value, ΔQ(t_{Dis-i}) represents the heat value of the battery cell to be detected at each discharging phase calculated according to the second formula, and Dis-i represents an index reflecting the number of time periods marked in the discharging phases of the battery cell to be detected.

For example, after calculating the heat value of each charging or discharging phase using the second formula, the heat values of the multiple charging phases are summed to obtain the first heat value (i.e., the third formula), and the heat values of the multiple discharging phases are summed to obtain the second heat value (i.e., the fourth formula).

Optionally, after determining the charging and discharging phases of the battery cell to be detected, the method for detecting aging of the battery cell further includes: calculating a first electric energy and a second electric energy of the battery cell to be detected, where the first electric energy is the sum of electric energies of the battery cell to be detected in the multiple charging phases, and the second electric energy is the sum of electric energies of the battery cell to be detected in the multiple discharging phases.

Optionally, the step of calculating the first electric energy of the battery cell to be detected includes:
calculating the first electric energy of the battery cell to be detected using the sixth formula:

$${E}_{Char} = {\sum }_{Char - i} U ( {t}_{Char - i} ) * I ( {t}_{Char - i} ) Δ {t}_{Char - i}$$

where E_{Char} represents the first electric energy, U(t_{Char-i}) represents the voltage of the battery cell to be detected at moment of t_{Char-i}, I(t_{Char-i}) represents the current of the battery cell to be detected at moment of t_{Char-i}, Δt_{Char-i} represents the duration of each charging phase, and Char-i represents an index reflecting the number of time periods marked in the charging phases of the battery cell to be detected.

Optionally, the step of calculating the second electric energy of the battery cell to be detected includes:
calculating the second electric energy of the battery cell to be detected using the seventh formula:

$${E}_{Dis} = {\sum }_{Dis - i} U ( {t}_{Dis - i} ) * I ( {t}_{Dis - i} ) Δ {t}_{Dis - i}$$

where E_{Dis} represents the second electric energy, U(t_{Dis-i}) represents the voltage of the battery cell to be detected at moment of t_{Dis-i}, I(t_{Dis-i}) represents the current of the battery cell to be detected at moment of t_{Dis-i}, Δt_{Dis-i} represents the duration of each discharging phase, and Dis-i represents an index reflecting the number of time periods marked in the discharging phases of the battery cell to be detected.

Optionally, after obtaining the first electric energy and the second electric energy of the battery cell to be detected, the first electric energy, the second electric energy, the first heat value and the second heat value are utilized to determine a heat consumption ratio of the battery cell to be detected, where the formula for determining the heat consumption ratio is:

$${η}_{heat} ( t ) = \frac{{Q}_{Char} + {Q}_{Dis}}{{E}_{Char} - {E}_{Dis}} ,$$

where ηₕₑₐₜ(t) represents the heat consumption ratio of the battery cell to be detected.

For example, as shown in FIG. 3, the first region between the charging process curve and the discharging process curve represents the energy difference between charging and discharging E_{Char}−E_{Dis}. It should be noted that the preset heat threshold may be determined based on the heat consumption ratio ηₕₑₐₜ(t). Since the proportion related to heat consumption and electric energy consumption involves hidden variables such as battery types and non-thermal factors characterizing degradation, the same reversible heat ratio may correspond to different aging degrees belonging to different aging points in time. Therefore, the preset heat threshold set under selected heat-to-electric-energy ratio conditions is more accurate.

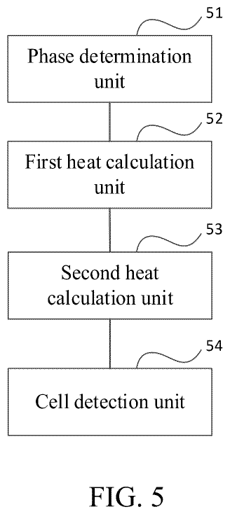

FIG. 5 is a structural diagram of a device for detecting aging of a battery cell, according to some embodiments of the present disclosure. As shown in FIG. 5, the device for detecting aging of a battery cell includes a phase determination unit 51, a first heat calculation unit 52, a second heat calculation unit 53, and a cell detection unit 54.

The phase determination unit 51 is configured to determine multiple charging phases and multiple discharging phases of the battery cell to be detected.

The first heat calculation unit 52 is configured to calculate a first heat value and a second heat value of the battery cell to be detected based on the mass, the composite specific heat capacity, and the temperature of the battery cell to be detected, where the first heat value is the sum of the heat generated in the multiple charging phases of the battery cell to be detected, and the second heat value is the sum of the heat generated in the multiple discharging phases of the battery cell to be detected.

The second heat calculation unit 53 is configured to calculate a reversible heat ratio of the battery cell to be detected based on the first heat value and the second heat value.

The cell detection unit 54 is configured to determine whether the battery cell to be detected has an aging issue based on the reversible heat ratio.

Optionally, the first heat calculation unit 52 further includes the following.

A coefficient calculation subunit is configured to determine a specific heat capacity mass coefficient of the battery cell to be detected based on the mass and the composite specific heat capacity of the battery cell to be detected.

A first heat calculation subunit is configured to calculate a heat value of each of the charging phases and the discharging phases, based on the specific heat capacity mass coefficient and the temperature of the battery cell to be detected.

A second heat calculation subunit is configured to sum the heat values of the charging phases to obtain the first heat value, and sum the heat values of the discharging phases to obtain the second heat value.

Optionally, the coefficient calculation subunit is configured to: determine the specific heat capacity mass coefficient of the battery cell to be detected, based on the mass and the composite specific heat capacity of the battery cell to be detected, using the first formula:

$${CM}_{Cell} ( t ) = ( {\sum }_{j} {C}_{j} ( t ) {M}_{j} ( t ) )$$

where CM_{Cell}(t) represents the specific heat capacity mass coefficient at moment t, Cⱼ(t) represents the composite specific heat capacity at moment t, Mⱼ(t) represents the mass of each material in the battery cell to be detected at moment t, and j represents an index reflecting the number of material types in the battery cell to be detected.

Optionally, the first heat calculation subunit is configured to: calculate the heat value of each charging or discharging phase, based on the specific heat capacity mass coefficient and the temperature of the battery cell to be detected, using the second formula:

$$Δ Q ( {t}_{n} ) = {\sum }_{n} {CM}_{Cell} ( {t}_{n} ) * Δ T ( {t}_{n} ) * Δ {t}_{n}$$

where ΔQ(tₙ) represents the heat value of each charging or discharging phase, CM_{Cell}(t) represents the specific heat capacity mass coefficient at moment t, ΔT(tₙ) represents the temperature of the battery cell to be detected at moment t, Δtₙ represents the duration of each charging or discharging phase, and n represents an index reflecting the number of time periods subdivided in each charging or discharging phase.

Optionally, the second heat calculation subunit is configured to: calculate the first heat value using the third formula:

$${Q}_{Char} = {\sum }_{Char - i} Δ Q ( {t}_{Char - i} )$$

where Q_{Char} represents the first heat value, ΔQ(t_{Char-i}) represents the heat value of the battery cell to be detected at each charging phase calculated according to the second formula, and Char-i represents an index reflecting the number of time periods marked in the charging phases of the battery cell to be detected; and
calculate the second heat value using the fourth formula:

$${ΔQ}_{Dis} = {\sum }_{Dis - i} Δ Q ( {t}_{Dis - i} )$$

where Q_{Dis} represents the second heat value, ΔQ(t_{Dis-i}) represents the heat value of the battery cell to be detected at each discharging phase calculated according to the second formula, and Dis-i represents an index reflecting the number of time periods marked in the discharging phases of the battery cell to be detected.

Optionally, the second heat calculation unit 53 is configured to calculate the reversible heat ratio of the battery cell to be detected using the fifth formula:

$${η}_{rev} ( t ) = \frac{\vert {Q}_{Char} - {Q}_{Dis} \vert / 2}{{Q}_{Char} + {Q}_{Dis}} ,$$

where Q_{Char} represents the first heat value, Q_{Dis} represents the second heat value, and ηᵣₑᵥ(t) represents the reversible heat ratio of the battery cell to be detected.

Optionally, the cell detection unit 54 is configured to: compare the reversible heat ratio with a preset heat threshold; and when the reversible heat ratio is less than the preset heat threshold, determine that the battery cell to be detected has an aging issue.

Optionally, the phase determination unit 51 is configured to detect a current direction of the battery cell to be detected within a preset time period, and determine a corresponding charging or discharging phase of the battery cell to be detected based on the detected current direction within the preset time period.

The device for detecting aging of a battery cell provided in the embodiments of the present disclosure may execute the method for detecting aging of a battery cell provided in any embodiment of the present disclosure, with the corresponding functional module and beneficial effect of executing the method.

In the description of the embodiments of the present disclosure, unless otherwise expressly specified and limited, the terms “mounted”, “connected”, “coupled” are to be understood broadly, e.g., it may be a fixed connection, a removable connection, or an integral connection; it may be a mechanical connection or an electrical connection; it may be a direct connection or an indirect connection through an intermediate medium; or it may refer to a communication between internal parts of two components. For a person of ordinary skill in the art, the specific meaning of the above terms in the present disclosure may be understood in specific cases.

Embodiments of the present disclosure also provide a computer device. The computer device includes one or more processors, a memory, and one or more applications, where the one or more applications are stored in the memory and configured to cause, when executed by the one or more processors, the one or more processors to perform the steps in the method for detecting aging of a battery cell in any of the above embodiments of the method for detecting aging of a battery cell.

For example, the computer device may include components such as a processor with one or more processing cores, a memory with one or more computer-readable storage media, a power supply, and an input unit.

The processor serves as the control center of the computer device. It connects various components of the computer device through multiple interfaces and circuits, and performs various functions and data processing tasks by executing software programs and/or modules stored in the memory and accessing data stored therein, thereby achieving overall control and monitoring of the computer device. Optionally, the processor may include one or more processing cores. Preferably, the processor may integrate an application processor and a modem processor, where the application processor is primarily responsible for processing tasks related to the operating system, user interface, and applications, while the modem processor mainly handles wireless communication. It is understood that the modem processor described above may alternatively be provided separately from the processor.

The memory may be configured to store software programs and modules. The processor executes various functional applications and performs data processing by running the software programs and modules stored in the memory. The memory may primarily include a program storage region and a data storage region. The program storage region may store an operating system and at least one application required for specific functions (e.g., audio playback function, image playback function, etc.), while the data storage region may store data created during the operation of the computer device. In addition, the memory may include high-speed random access memory and non-volatile memory, such as at least one disk storage device, flash memory device, or other non-volatile solid-state memory devices. Accordingly, the memory may further include a memory controller for providing the processor with access to the memory.

The computer device further includes a power supply configured to supply power to various components. Preferably, the power supply is operatively connected to the processor logic via a power management system, such that charging, discharging, and power consumption management can be realized through the power management system. The power supply may include one or more DC or AC power sources, a rechargeable system, a power failure detection circuit, a power converter or inverter, a power status indicator, or any other suitable component.

The computer device may further includes an input unit configured to receive numeric or character input, and to generate input signals such as keyboard, mouse, joystick, optical, or trackball signals, which relate to user settings and functional control.

Although not illustrated, the computer device may also include a display unit, which will not be described in detail herein. For example, in the present embodiments, the processor of the computer device may be configured to execute instructions to load one or more executable files corresponding to application processes into the memory, and run, via the processor, the application programs stored in the memory to perform multiple functions, where the instructions are as follows.

Multiple charging phases and multiple discharging phases of the battery cell to be detected are determined.

A first heat value and a second heat value of the battery cell to be detected are calculated based on the mass, the composite specific heat capacity, and the temperature of the battery cell to be detected, where the first heat value is the sum of the heat generated in the multiple charging phases of the battery cell to be detected, and the second heat value is the sum of the heat generated in the multiple discharging phases of the battery cell to be detected.

A reversible heat ratio of the battery cell to be detected is calculated based on the first heat value and the second heat value.

It is determined whether the battery cell to be detected has an aging issue based on the reversible heat ratio.

Embodiments of the present disclosure provide a method and device for detecting aging of a battery cell, and a computer device. The method includes: determining multiple charging phases and multiple discharging phases of the battery cell to be detected; calculating a first heat value and a second heat value of the battery cell to be detected based on the mass, the composite specific heat capacity, and the temperature of the battery cell to be detected; calculating a reversible heat ratio of the battery cell to be detected based on the first heat value and the second heat value; and determining whether the battery cell to be detected has an aging issue based on the reversible heat ratio. According to the embodiments of the present disclosure, the charging and discharging phases of the battery cell to be detected are divided, the reversible heat ratio is calculated based on the heat generated by the battery cell to be detected during the charging and discharging phases, and the reversible heat ratio is then used to determine whether the battery cell is experiencing aging. This addresses the absence in the related art of aging detection based on temperature variation characteristics, enabling real-time monitoring of battery cell aging using temperature variation characteristics of the battery cell. As a result, it simplifies the detection process and reduces detection costs.

It should be understood by those skilled in the art that all or part of the steps of the above methods in the embodiments may be implemented by instructions or by controlling relevant hardware using such instructions. These instructions may be stored in a computer-readable storage medium and loaded and executed by a processor.

In practice, the above units or structures may be implemented as independent entities or in any suitable combination as one or more entities. The specific implementation of the above units or structures may refer to the foregoing method embodiments, and will not be described again herein.

What is claimed is:

1. A method for detecting aging of a battery cell, comprising:
determining a plurality of charging phases and a plurality of discharging phases of the battery cell to be detected;
calculating a first heat value and a second heat value of the battery cell to be detected based on a mass, a composite specific heat capacity, and a temperature of the battery cell to be detected, wherein the first heat value is a sum of heat generated in the plurality of charging phases of the battery cell to be detected, and the second heat value is a sum of heat generated in the plurality of discharging phases of the battery cell to be detected;
calculating a reversible heat ratio of the battery cell to be detected based on the first heat value and the second heat value; and
determining whether the battery cell to be detected has an aging issue based on the reversible heat ratio.

2. The method for detecting aging of a battery cell according to claim 1, wherein the calculating of the first heat value and the second heat value of the battery cell to be detected based on the mass, the composite specific heat capacity, and the temperature of the battery cell to be detected comprises:
determining a specific heat capacity mass coefficient of the battery cell to be detected based on the mass and the composite specific heat capacity of the battery cell to be detected;
calculating a heat value of each of the plurality of charging phases and the plurality of discharging phases, based on the specific heat capacity mass coefficient and the temperature of the battery cell to be detected; and
summing the heat values of the plurality of charging phases to obtain the first heat value, and summing the heat values of the plurality of discharging phases to obtain the second heat value.

3. The method for detecting aging of a battery cell according to claim 2, wherein the determining of the specific heat capacity mass coefficient of the battery cell to be detected based on the mass and the composite specific heat capacity of the battery cell to be detected comprises:
determining the specific heat capacity mass coefficient of the battery cell to be detected, based on the mass and the composite specific heat capacity of the battery cell to be detected, using a first formula:
$$C {M}_{Cell} ( t ) = ( {\sum }_{j} {C}_{j} ( t ) {M}_{j} ( t ) )$$
wherein CM_{Cell}(t) represents the specific heat capacity mass coefficient at moment t, Cⱼ(t) represents the composite specific heat capacity at moment t, Mⱼ(t) represents a mass of each material in the battery cell to be detected at moment t, and j represents an index reflecting a number of material types in the battery cell to be detected.

4. The method for detecting aging of a battery cell according to claim 2, wherein the calculating of the heat value of each of the plurality of charging phases and the plurality of discharging phases based on the specific heat capacity mass coefficient and the temperature of the battery cell to be detected comprises:
calculating the heat value of each charging or discharging phase, based on the specific heat capacity mass coefficient and the temperature of the battery cell to be detected, using a second formula:
$$Δ Q ( {t}_{n} ) = {\sum }_{n} {CM}_{Cell} ( {t}_{n} ) * Δ T ( {t}_{n} ) * Δ {t}_{n}$$
wherein ΔQ(tₙ) represents the heat value of each charging or discharging phase, CM_{Cell}(t) represents the specific heat capacity mass coefficient at moment t, ΔT(tₙ) represents the temperature of the battery cell to be detected at moment t, Δtₙ represents a duration of each charging or discharging phase, and n represents an index reflecting a number of time periods subdivided in each charging or discharging phase.

5. The method for detecting aging of a battery cell according to claim 4, wherein the summing of the heat values of the plurality of charging phases to obtain the first heat value and the summing of the heat values of the plurality of discharging phases to obtain the second heat value comprise:
calculating the first heat value using a third formula:
$${Q}_{Char} = {\sum }_{Char - i} Δ Q ( {t}_{Char - i} )$$
wherein Q_{Char} represents the first heat value, ΔQ(t_{Char-i}) represents the heat value of the battery cell to be detected at each charging phase calculated according to the second formula, and Char-i represents an index reflecting a number of time periods marked in the plurality of charging phases of the battery cell to be detected; and
calculating the second heat value using a fourth formula:
$${Q}_{Dis} = {\sum }_{Dis - i} Δ Q ( {t}_{Dis - i} )$$
wherein Q_{Dis} represents the second heat value, ΔQ(t_{Dis-i}) represents the heat value of the battery cell to be detected at each discharging phase calculated according to the second formula, and Dis-i represents an index reflecting a number of time periods marked in the plurality of discharging phases of the battery cell to be detected.

6. The method for detecting aging of a battery cell according to claim 1, wherein the calculating of the reversible heat ratio of the battery cell to be detected based on the first heat value and the second heat value comprises:
calculating the reversible heat ratio of the battery cell to be detected using a fifth formula:
$${η}_{rev} ( t ) = \frac{\vert {Q}_{Char} - {Q}_{Dis} \vert / 2}{{Q}_{Char} + {Q}_{Dis}}$$
wherein Q_{Char} represents the first heat value, Q_{Dis} represents the second heat value, and ηᵣₑᵥ(t) represents the reversible heat ratio of the battery cell to be detected.

7. The method for detecting aging of a battery cell according to claim 1, wherein the determining of whether the battery cell to be detected has an aging issue based on the reversible heat ratio comprises:
comparing the reversible heat ratio with a preset heat threshold; and
determining that the battery cell to be detected has an aging issue when the reversible heat ratio is less than the preset heat threshold.

8. The method for detecting aging of a battery cell according to claim 1, wherein the determining of the plurality of charging phases and the plurality of discharging phases of the battery cell to be detected comprises:
detecting a current direction of the battery cell to be detected within a preset time period, and determining a corresponding charging or discharging phase of the battery cell to be detected based on the detected current direction within the preset time period.

9. The method for detecting aging of a battery cell according to claim 1, further comprising:
calculating a first electric energy and a second electric energy of the battery cell to be detected, wherein the first electric energy is a sum of electric energies of the battery cell to be detected in the plurality of charging phases, and the second electric energy is a sum of electric energies of the battery cell to be detected in the plurality of discharging phases.

10. The method for detecting aging of a battery cell according to claim 9, wherein the calculating of the first electric energy and the second electric energy of the battery cell to be detected comprises:
calculating the first electric energy of the battery cell to be detected using a sixth formula:
$${E}_{Char} = {\sum }_{Char - i} U ( {t}_{Char - i} ) * I ( {t}_{Char - i} ) Δ {t}_{Char - i}$$
wherein E_{Char} represents the first electric energy, U(t_{Char-i}) represents a voltage of the battery cell to be detected at moment of t_{Char-i}, I(t_{Char-i}) represents a current of the battery cell to be detected at moment of t_{Char-i}, Δt_{Char-i} represents a duration of each charging phase, and Char-i represents an index reflecting a number of time periods marked in the plurality of charging phases of the battery cell to be detected; and
calculating the second electric energy of the battery cell to be detected using a seventh formula:
$${E}_{Dis} = {\sum }_{Dis - i} U ( {t}_{Dis - i} ) * I ( {t}_{Dis - i} ) Δ {t}_{Dis - i}$$
wherein E_{Dis} represents the second electric energy, U(t_{Dis-i}) represents a voltage of the battery cell to be detected at moment of t_{Dis-i}, I(t_{Dis-i}) represents a current of the battery cell to be detected at moment of t_{Dis-i}, Δt_{Dis-i} represents a duration of each discharging phase, and Dis-i represents an index reflecting a number of time periods marked in the plurality of discharging phases of the battery cell to be detected.

11. The method for detecting aging of a battery cell according to claim 9, further comprising:
determining a heat consumption ratio of the battery cell to be detected based on the first electric energy, the second electric energy, the first heat value and the second heat value;
wherein a formula for determining the heat consumption ratio is:
$${η}_{heat} ( t ) = \frac{{Q}_{Char} + {Q}_{Dis}}{{E}_{Char} - {E}_{Dis}} ,$$
wherein ηₕₑₐₜ(t) represents the heat consumption ratio of the battery cell to be detected, Q_{Char} represents the first heat value, Q_{Dis} represents the second heat value, E_{Char} represents the first electric energy, and E_{Dis} represents the second electric energy.

12. A computer device, comprising:
one or more processors;
a memory; and
one or more applications, wherein the one or more applications are stored in the memory and configured to cause, when executed by the one or more processors, the one or more processors to perform:
determining a plurality of charging phases and a plurality of discharging phases of a battery cell to be detected;
calculating a first heat value and a second heat value of the battery cell to be detected based on a mass, a composite specific heat capacity, and a temperature of the battery cell to be detected, wherein the first heat value is a sum of heat generated in the plurality of charging phases of the battery cell to be detected, and the second heat value is a sum of heat generated in the plurality of discharging phases of the battery cell to be detected;
calculating a reversible heat ratio of the battery cell to be detected based on the first heat value and the second heat value; and
determining whether the battery cell to be detected has an aging issue based on the reversible heat ratio.

13. The computer device according to claim 12, wherein the one or more applications are configured to cause, when executed by the one or more processors, the one or more processors to perform the calculating of the first heat value and the second heat value of the battery cell to be detected based on the mass, the composite specific heat capacity, and the temperature of the battery cell to be detected by:
determining a specific heat capacity mass coefficient of the battery cell to be detected based on the mass and the composite specific heat capacity of the battery cell to be detected;
calculating a heat value of each of the plurality of charging phases and the plurality of discharging phases, based on the specific heat capacity mass coefficient and the temperature of the battery cell to be detected; and
summing the heat values of the plurality of charging phases to obtain the first heat value, and summing the heat values of the plurality of discharging phases to obtain the second heat value.

14. The computer device according to claim 13, wherein the one or more applications are configured to cause, when executed by the one or more processors, the one or more processors to perform the determining of the specific heat capacity mass coefficient of the battery cell to be detected based on the mass and the composite specific heat capacity of the battery cell to be detected by:
determining the specific heat capacity mass coefficient of the battery cell to be detected, based on the mass and the composite specific heat capacity of the battery cell to be detected, using a first formula:
$$C {M}_{C e l l} ( t ) = ( {\sum }_{j} {C}_{j} ( t ) {M}_{j} ( t ) )$$
wherein CM_{Cell}(t) represents the specific heat capacity mass coefficient at moment t, Cⱼ(t) represents the composite specific heat capacity at moment t, Mⱼ(t) represents a mass of each material in the battery cell to be detected at moment t, and j represents an index reflecting a number of material types in the battery cell to be detected.

15. The computer device according to claim 13, wherein the one or more applications are configured to cause, when executed by the one or more processors, the one or more processors to perform the calculating of the heat value of each of the plurality of charging phases and the plurality of discharging phases based on the specific heat capacity mass coefficient and the temperature of the battery cell to be detected by:
calculating the heat value of each charging or discharging phase, based on the specific heat capacity mass coefficient and the temperature of the battery cell to be detected, using a second formula:
$$Δ Q ( {t}_{n} ) = {\sum }_{n} C {M}_{Cell} ( {t}_{n} ) * Δ T ( {t}_{n} ) * Δ {t}_{n}$$
wherein ΔQ(tₙ) represents the heat value of each charging or discharging phase, CM_{Cell}(t) represents the specific heat capacity mass coefficient at moment t, ΔT(tₙ) represents the temperature of the battery cell to be detected at moment t, Δtₙ represents a duration of each charging or discharging phase, and n represents an index reflecting a number of time periods subdivided in each charging or discharging phase.

16. The computer device according to claim 15, wherein the one or more applications are configured to cause, when executed by the one or more processors, the one or more processors to perform the summing of the heat values of the plurality of charging phases to obtain the first heat value and the summing of the heat values of the plurality of discharging phases to obtain the second heat value by:
calculating the first heat value using a third formula:
$${Q}_{Char} = {\sum }_{Char - i} Δ Q ( {t}_{Char - i} )$$
wherein Q_{Char} represents the first heat value, ΔQ(t_{Char-i}) represents the heat value of the battery cell to be detected at each charging phase calculated according to the second formula, and Char-i represents an index reflecting a number of time periods marked in the plurality of charging phases of the battery cell to be detected; and
calculating the second heat value using a fourth formula:
$${Q}_{Dis} = {\sum }_{Dis - i} Δ Q ( {t}_{Dis - i} )$$
wherein Q_{Dis} represents the second heat value, ΔQ(t_{Dis-i}) represents the heat value of the battery cell to be detected at each discharging phase calculated according to the second formula, and Dis-i represents an index reflecting a number of time periods marked in the plurality of discharging phases of the battery cell to be detected.

17. The computer device according to claim 12, wherein the one or more applications are configured to cause, when executed by the one or more processors, the one or more processors to perform the calculating of the reversible heat ratio of the battery cell to be detected based on the first heat value and the second heat value by:
calculating the reversible heat ratio of the battery cell to be detected using a fifth formula:
$${η}_{rev} ( t ) = \frac{\vert {Q}_{Char} - {Q}_{Dis} \vert / 2}{{Q}_{Char} + {Q}_{Dis}}$$
wherein Q_{Char} represents the first heat value, Q_{Dis} represents the second heat value, and ηᵣₑᵥ(t) represents the reversible heat ratio of the battery cell to be detected.

18. The computer device according to claim 12, wherein the one or more applications are configured to cause, when executed by the one or more processors, the one or more processors to perform the determining of whether the battery cell to be detected has an aging issue based on the reversible heat ratio by:
comparing the reversible heat ratio with a preset heat threshold; and
determining that the battery cell to be detected has an aging issue when the reversible heat ratio is less than the preset heat threshold.

19. The computer device according to claim 12, wherein the one or more applications are configured to cause, when executed by the one or more processors, the one or more processors to perform the determining of the plurality of charging phases and the plurality of discharging phases of the battery cell to be detected by:
detecting a current direction of the battery cell to be detected within a preset time period, and determining a corresponding charging or discharging phase of the battery cell to be detected based on the detected current direction within the preset time period.

20. The computer device according to claim 12, wherein the one or more applications are configured to cause, when executed by the one or more processors, the one or more processors to perform:
calculating a first electric energy and a second electric energy of the battery cell to be detected, wherein the first electric energy is a sum of electric energies of the battery cell to be detected in the plurality of charging phases, and the second electric energy is a sum of electric energies of the battery cell to be detected in the plurality of discharging phases.
